(19) United States
(12) Patent Application Publication
(10) Pub. No.: US 2020/0355494 A1
(43) Pub. Date: Nov. 12, 2020

(54) STRUCTURED LIGHT PROJECTION

(71) Applicant: Heptagon Micro Optics Pte. Ltd., Singapore (SG)

(72) Inventor: Markus Rossi, Singapore (SG)

(21) Appl. No.: 16/642,200

(22) PCT Filed: Aug. 28, 2018
(86) PCT No.: PCT/SG2018/050433

§ 371 Date: Feb. 26, 2020

Related U.S. Application Data
(60) Provisional application No. 62/551,012, filed on Aug. 28, 2017.

(51) Int. Cl. G01B 11/25; G02B 27/42

(52) U.S. Cl. CPC G01B 11/2536; H01S 5/423; G02B 27/4277; G02B 27/425

(57) ABSTRACT

A structured light projection system includes an array of light emitting elements operable, collectively, to emit a regular pattern of light. A first optical element is configured to alter the pattern of light emitted by the array of light emitting elements to generate a first irregular pattern of light, and a second optical element is configured to receive the irregular pattern of light generated by the first optical element and to produce a pattern comprising multiple instances of the first irregular pattern.

### CROSS-REFERENCE TO RELATED APPLICATION(S)

The present application claims the benefit of priority of U.S. Provisional Patent Application No. 62/551,012, filed on Aug. 28, 2017. The contents of the prior application are incorporated herein by reference.

### FIELD OF THE DISCLOSURE

The present disclosure relates to structured light projection.

### BACKGROUND

Various imaging applications use compact optoelectronic modules that can be integrated, for example, within host computing devices such as smart phones, tablets, laptops or personal computers. In some applications, the module includes a light source to project a structured light pattern onto a scene that includes one or more objects of interest. In some structured-light assemblies, a pattern is projected onto a subject, an image of the pattern is obtained, the projected pattern is compared to the collected pattern, and differences between the two patterns are correlated with depth information. Thus, distortions in the pattern are correlated with depth. Such techniques can be useful for low-light and low-texture objects or scenes because the structured light can provide additional texture (e.g., for matching pixels in the stereo images).

### SUMMARY

The present disclosure describes techniques for creating an irregular structured light pattern using a regular array of light emitting elements.

For example, in one aspect, the disclosure describes a method of creating an irregular structured light pattern from a regular array of light emitting elements. The method includes generating a regular pattern of light from a uniformly distributed array of light emitting elements, altering the regular pattern of light to generate an irregular pattern of light, and reproducing the irregular pattern of light in multiple instances arranged adjacent one another.

One or more of the following features are present in some implementations. For example, the array of light emitting elements can include columns and rows of light emitting elements, wherein the rows are arranged perpendicularly relative to the columns or wherein the rows are angled relative to the columns. In some implementations, the array of light emitting elements produces a regular pattern of a sub pattern of lights. In some cases, the array of light emitting elements produces a grid of a cluster of lights, wherein the grid has commonly shaped clusters in a first direction, and wherein the grid has differently shaped clusters in a second direction perpendicular to the first direction.

In some implementations, the method included receiving light emitted from the array of light emitting elements and projecting the light to a first diffractive optical element to generate the irregular pattern of light. The irregular pattern of light may be, for example, at least one of a randomized, non-uniform, non-grid, disrupted, unevenly spaced, partially obstructed, partially blocked, and/or non-equally distributed pattern.

In some cases, reproducing the irregular pattern in multiple instances includes producing a uniform distribution of the irregular pattern. Reproducing the irregular pattern of light may include producing a tiled pattern, producing multiple interlaced instances of the irregular pattern of light, and/or producing multiple partially overlapping instances of the irregular pattern of light.

This disclosure also describes a structured light projection system that includes an array of light emitting elements operable, collectively, to emit a regular pattern of light. The system further includes a first optical element configured to alter the pattern of light emitted by the array of light emitting elements to generate a first irregular pattern of light, and a second optical element configured to receive the irregular pattern of light generated by the first optical element and to produce a pattern comprising multiple instances of the first irregular pattern.

One or more of the following features are present in some implementations. For example, the array of light emitting elements can include columns and rows of light emitting elements, wherein the rows are arranged perpendicularly relative to the columns or wherein the rows are angled relative to columns. In some cases, the array of light emitting elements is operable to project a regular pattern of a sub pattern of lights. In some implementations, the array of light emitting elements is operable to project a grid of a cluster of lights, wherein the grid has commonly shaped clusters in a first direction, and wherein the grid has differently shaped clusters in a second direction perpendicular to the first direction. The light emitting elements can be, for example, VCSELs.

The first irregular pattern of light can be, for example, at least one of a randomized, non-uniform, non-grid, disrupted, unevenly spaced, partially obstructed, partially blocked, and/or non-equally distributed pattern.

The structured light projection system can further include a projection lens system operable to receive light emitted from the array of light emitting elements and to project the light to the first optical element. The second optical element can be arranged to produce a uniform distribution of the irregular pattern, a tiled pattern, multiple interlaced instances of the irregular pattern of light, and/or multiple partially overlapping instances of the irregular pattern of light.

In some implementations, each of the first and second optical elements comprises a diffractive optical element.

The present disclosure also describes an optical sensor module that includes an optical source including a structured light projection system operable to project a structured light pattern onto an object. The module also includes an optical sensor to sense light reflected back from the object illuminated by the structured light pattern, and processing circuitry operable to determine a physical characteristic of the object based at least in part on a signal from the optical sensor. The disclosure also describes a host device (e.g., a smartphone) that includes the optical sensor module, wherein the host device is operable to use data obtained by the optical sensor of the optical sensor module for one or more functions executed by the host device.

Various advantages can be achieved in some implementations. For example, the disclosed subject matter can facilitate producing structured light patterns that can enhance three-dimensional imaging or other systems and may be used to enhance the operation of smartphones and other computing devices that incorporate a structured light projection system as described here.

Other aspects, features and advantages will be readily apparent from the following detailed description, the accompanying drawings and the claims.

### BRIEF DESCRIPTION OF THE DRAWINGS

FIG. 1 illustrates an example of a structured light projection system.

FIGS. 2, 3, 4, 5 and 6 illustrate examples of arrays of light emitting elements arranged in a regular pattern.

FIG. 7 illustrates an example of a structured light projection system of arranged to produce a tiled light pattern.

FIG. 8 illustrates an example of a structured light projection system of arranged to produce an interlaced light pattern.

FIG. 9 illustrates an example of a projection lens system.

FIG. 10 illustrates an example of a diffractive optical element.

FIG. 11 illustrates an example of a module that incorporated a structured light projection system.

FIG. 12 illustrates an example of a host device that incorporates a structured light projection system.

### DETAILED DESCRIPTION

The present disclosure describes techniques for creating an irregular structured light pattern using a regular array of light emitting elements. As described in greater detail below, a method can include generating a regular pattern of light from a regular array of light emitting elements (e.g., a uniformly distributed array of vertical-cavity surface-emitting lasers (VCSELs)). The regular pattern of light can be, for example, a uniformly distributed pattern, a grid-like pattern, or other regular pattern. The method includes altering the regular pattern of light emitted to generate an irregular representation of light, and reproducing the irregular representation of light as multiple instances arranged adjacent one another.

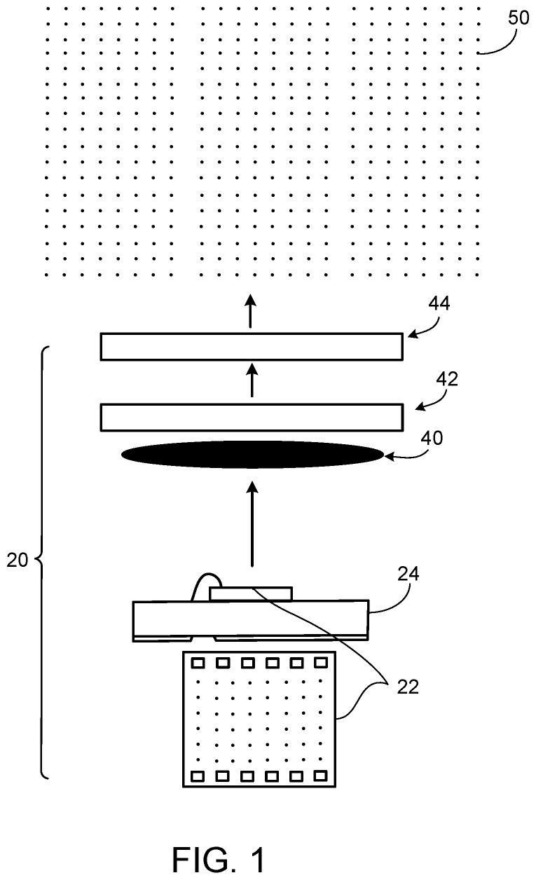

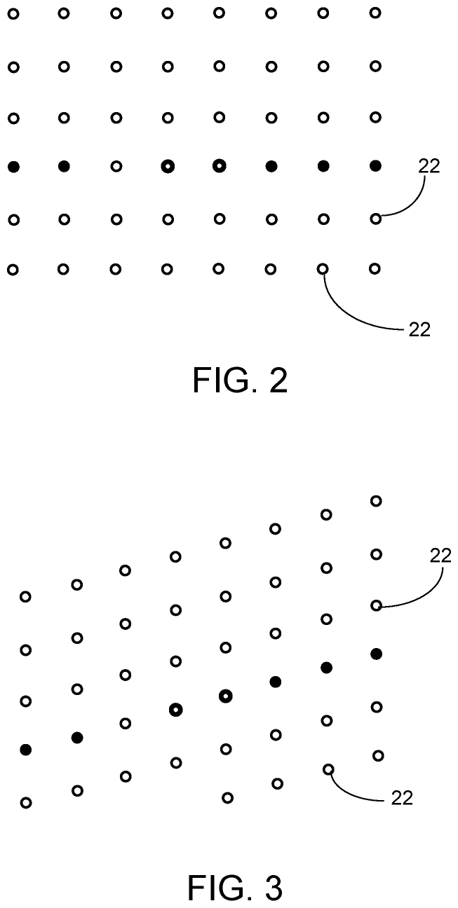

FIG. 1 illustrates an example of a structured light projection system 20 in accordance with some implementations. The system is operable to carry out various methods described in this disclosure. As shown in FIG. 1, the system 20 includes an array of light emitting elements such as VCSELs 22, which can be mounted, for example, on a substrate in a module 24. The VCSELs 22 can be arranged in a regular pattern. FIGS. 2 and 3 illustrate examples of regular patterns of the VCSELs. In particular, FIGS. 2 and 3 depict examples in which the VCSEL array projects a regular (e.g., grid) pattern of light. The regular pattern represents a repeated (e.g., consistent) pattern of light emitting elements. In some cases, the regular pattern includes columns and rows of light emitting elements that are arranged generally perpendicularly relative to one another (see FIG. 2). For example, the array of light emitting devices 22 can be arranged as a grid (e.g., a 12×9 grid) of light emitting devices. In some cases, the regular pattern of light can include an angled (e.g., slanted) regular pattern. Thus, in some implementations, the regular pattern includes columns and rows of light emitting elements in which rows are angled (e.g., non-perpendicular or offset) with respect to the direction of columns (see FIG. 3).

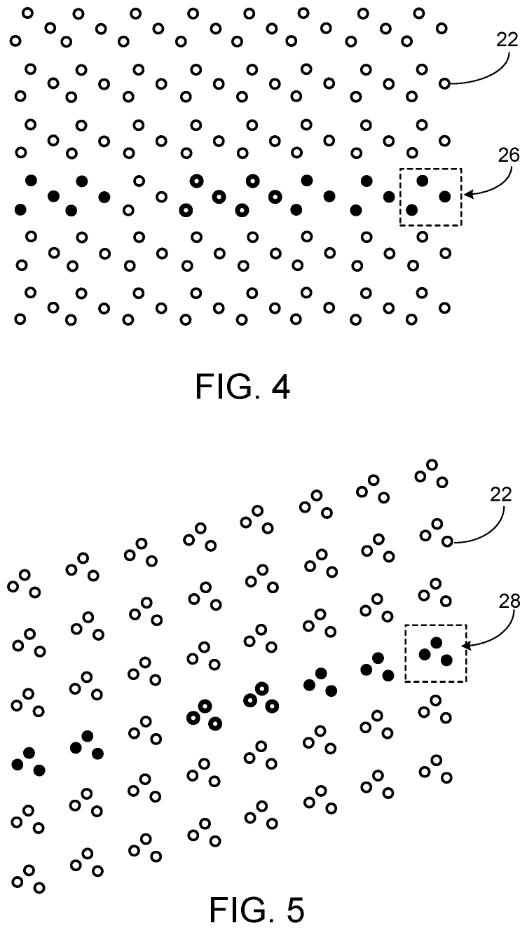

FIGS. 4 and 5 depict examples in which the VCSEL array projects a regular pattern of a sub pattern 26 or 28 of lights (e.g., a grid of smaller clusters of light). In some cases, the regular pattern includes columns and rows of clusters 26 (or 28) of light emitting elements 22, where the clusters are arranged generally perpendicularly relative to one another (see FIG. 4). In some cases, the regular pattern of light can include an angled (e.g., slanted) regular pattern of clusters 28 (see FIG. 5). Thus, in some implementations, the regular pattern includes columns and rows of clusters 28 of light emitting elements 22 in which rows of clusters 28 are angled (e.g., non-perpendicular) with respect to the direction of columns.

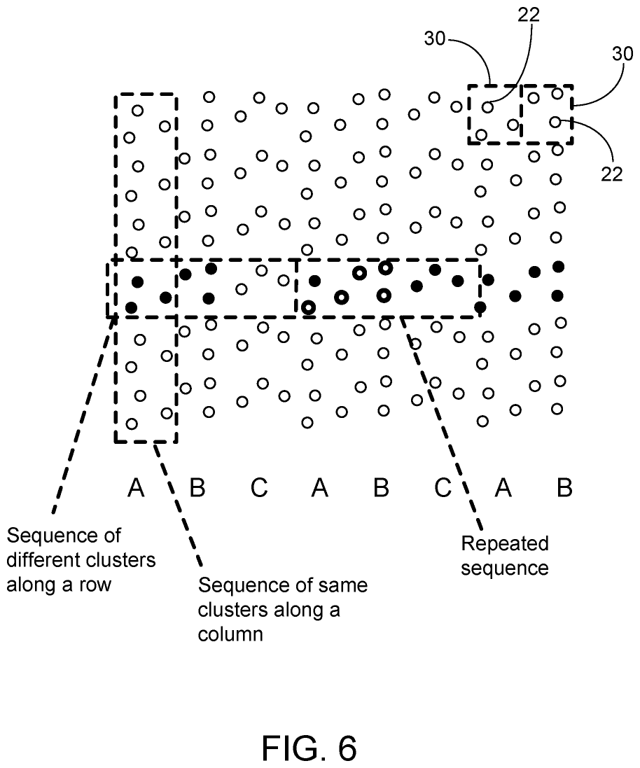

FIG. 6 depicts another example in which the VCSEL array projects a regular pattern of a sub pattern of lights (e.g., a grid of smaller clusters of light) that have commonly shaped clusters 30 in one direction of the grid (e.g., along columns or the y-axis) and differently shaped clusters in a different direction of the grid (e.g., along rows or the x-axis). In some cases, as depicted, the grid has a sequence of differently shaped clusters from column to column (e.g., marked A, B, and C in FIG. 6). In some implementations, the sequence of differently shaped clusters along a row is repeated (e.g., A, B, C, A, B, C, etc.).

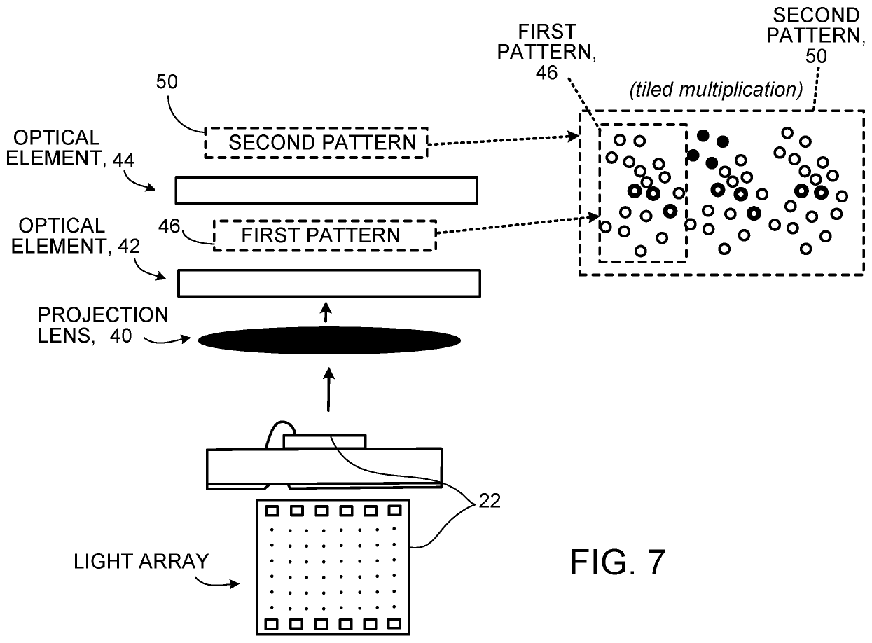

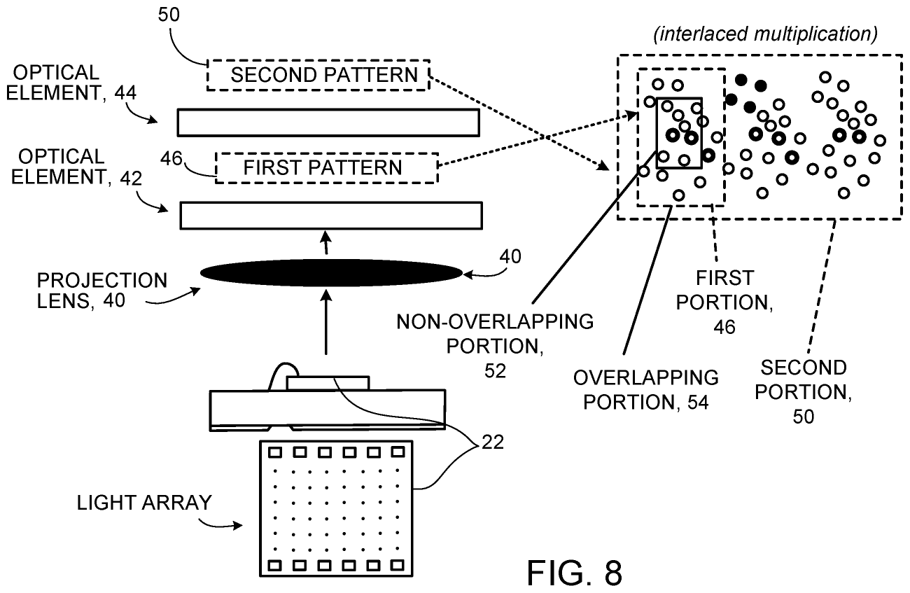

The system 20 of FIG. 1 also includes a projection lens system 40 and first and second optical elements 42, 44. As illustrated by FIGS. 7 and 8, the projection lens system 40 is configured to receive light emitted from the array of VCSELs 22 and to project the light to the first optical element 42. The first optical element 42 is configured to alter the pattern of light emitted by the array of VCSELs 22 to generate a first emitted irregular pattern 46 of light. The irregular pattern 46 can be, for example, a randomized, non-uniform, non-grid, disrupted, unevenly spaced, partially obstructed, partially blocked, and/or non-equally distributed pattern. The second optical element 44 is configured to receive the irregular pattern 46 of light generated by the first optical element 42 and to reproduce the first emitted pattern in a second emitted pattern 50 that comprises multiple instances of the first emitted pattern 46 arranged, for example, in a tiled pattern (see FIG. 7). The second optical element 44 can reproduce the first emitted pattern 46, for example, by tiling, distributing and/or duplicating the first emitted pattern. The pattern 50 produced by the second optical element 44 can be, for example, a regular or uniformly distributed pattern of multiple instances of the first pattern 46. Thus, in some implementations, the pattern of light emitted collectively from the light emitting devices 22 is a uniformly distributed pattern of light, the first emitted pattern 46 is an irregular pattern, and the second emitted pattern 50 is a uniform distribution of the irregular pattern.

In some implementations, the tiled pattern 50 comprises adjacent instances of the first emitted pattern 46 separated from one another. In some implementations, the tiled pattern 50 comprises multiple instances of the first emitted pattern 46 arranged in a series of columns and rows. In some cases, the arrangement comprises a matrix, such as a 3×3 matrix or a 2 by 2 matrix.

In some implementations, the second emitted pattern 50 comprises multiple interlaced, or at least partially overlapping, instances of the first emitted pattern 46 (see FIG. 8). In some cases, the overlapping patterns include at least one element of a first pattern instance being disposed within or between multiple elements of a second pattern instance. In some implementations, despite adjacent instances at least partially overlapping with one another, at least some portions of the individual instances (e.g., a central region, a majority portion, or a majority portion of a central region) can be unobstructed by an adjacent instance. That is, in some cases, adjacent instances (e.g., tiles) can partially overlap one another, yet remain substantially distinct (e.g., unaltered) by surrounding tiles. In some cases, each of the overlapping tiles is at least 20% non-overlapping or in some cases, even more (e.g., at least 30%, 40%, 50%, 60%, 70%, 80%, 90% or 95%), where the non-overlapping portions of the tiles are representative of the pattern of light provided to the second optical element (i.e., the first pattern). As depicted in FIG. 8, the interlaced tiles can include a central non-overlapping portion 52 and an outer overlapping portion (e.g., an overlapping border) 54 that overlaps with an outer overlapping portion of an adjacent tile.

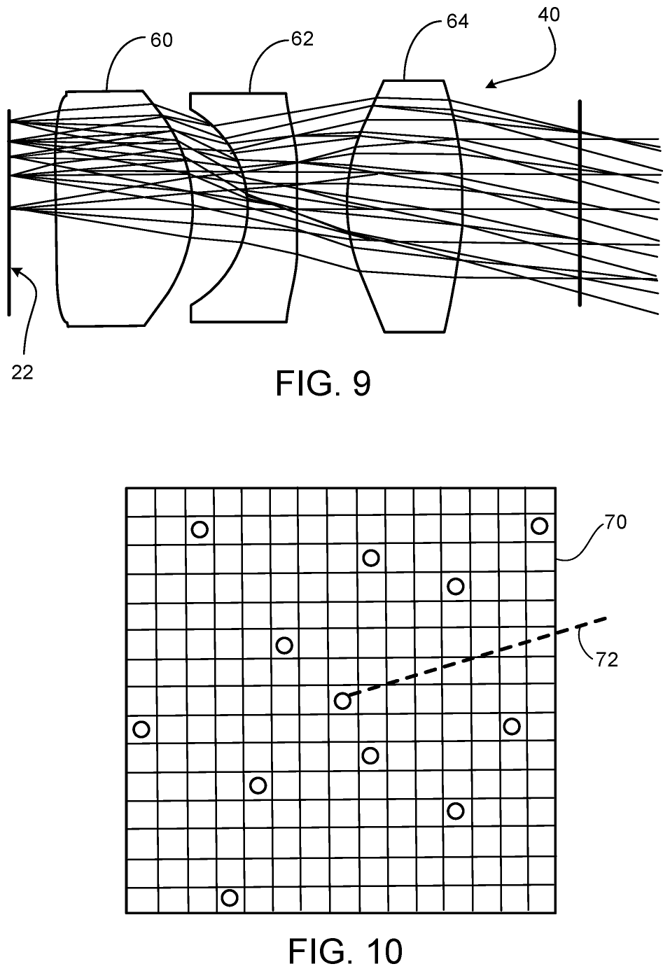

FIG. 9 depicts an example of the projection lens system 40, which can include one or more optical components arranged to project light from the light emitting elements 22. Various configurations of the optical components are possible. For example, the projection lens 40 can include one or more lens elements 60, 62, 64 arranged linearly, and which may be formed by any suitable manufacturing technique (e.g., injection molding or wafer-level manufacturing techniques). The specific optical properties of the projection lens system 40 can be adapted for specific applications. In some implementations, the projection lens system 40 has an effective focal length that is less than or equal to about 5 millimeters (mm) (e.g., in the range of 1.5 mm-5 mm) In some cases, the projection lens has an object field height that is less than or equal to about 1 mm (e.g., in the range of 0.2 mm-1.0 mm) Additionally, specific configurations of lens types can be adapted for particular applications. In some implementations, at least one lens element is telecentric on an object side of the projection lens system 40, with no system aperture. However, in some implementations, the projection lens system 40 includes non-telecentric lens designs (e.g., chief ray angle (CRA)< >0 deg) and uses one or more system apertures.

The optical elements 42, 44 can be implemented, for example, as respective diffractive optical elements, which are operable to create the desired patterns of light from the light produced by the regular array of light emitting elements 22. In some implementations, one or both of the diffractive optical elements 42, 44 includes a respective diffraction grating (e.g., a two-dimensional grating) 70 that splits an incoming beam 72 (see FIG. 10). For example, an incoming beam entering the diffractive optical element 42 may be emitted from a single light emitting element (e.g., VCSEL) after having been collimated by the projection lens system 40.

The diffractive optical elements 42, 44 can be formed in any suitable constructions. For example, in some cases, the diffractive optical element is formed as a binary transmission mask. In some instances, the diffractive optical element is formed as a phase element, which can include a surface relief profile with discrete levels, a continuous profile or any other optical microstructure that imposes an appropriate phase shift on the incoming wave. If the unit cell of the diffractive grating contains n×n pixels with N different phase levels (where N is an uneven number), a grid of n×n diffraction orders can be created. In the example of FIG. 10, which has 15×15 orders, twelve diffraction orders are chosen on randomly chosen positions in the grid. The diffractive optical element then can be configured (e.g., optimized) to illuminate only the desired diffraction orders. As a result, an irregular optical pattern can be produced.

As noted above, details of the various components of the system 20 can vary depending on the particular implementation. However, a particular implementation is operable to produce coded, structured light based on tiled, toroidal perfect sub-maps. In this case, the projected pattern can consist, for example, of repeating tiles, each of which is a two-dimensional toroidal perfect sub-map. Each dot in the pattern projected by the system is isolated and surrounded by zeros (i.e., no immediately adjacent dot of light). The pattern can have a very high level of randomness. Further, using a regular array, for example, of several hundred (e.g., 600) VCSELs, the projected pattern can have tens of thousands (e.g., 39,000) of dots, wherein at least about 75% of the dots are within the camera's field of view. The VCSEL array can have translational symmetry in the y-direction (or the x-direction). Further, some of the VCSELs may emit a wavelength (i.e., color) of light that differs from the wavelength emitted by other VCSELs in the array. The first diffractive element creates an uncorrelated dot pattern for the laser beams, and the second diffractive element multiplies the uncorrelated dot pattern into a matrix (e.g., 3×3) pattern. The divergence angles and fan-out angles can be optimized to project copies of the uncorrelated dot pattern are separated from one another by relatively large gaps. The final pattern projected by the system is, in some cases, color coded and uniform.

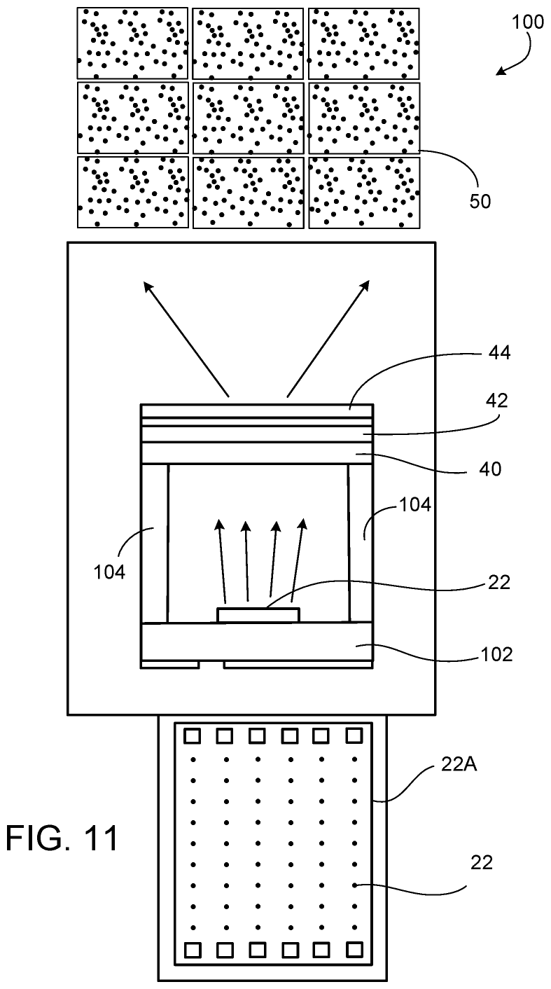

As illustrated in FIG. 11, the structured light projection system (including the regular array of VCSELs or other light emitting elements 22, the projection lens system 40 and the diffractive optical elements 42, 44) can be integrated as part of a module 100. The VCSELs 22 can be mounted over a printed circuit board or other substrate 102 that is separated from the optical components (e.g., 40, 42, 44) by a spacer 104 that establishes a well-defined distance between the VCSELs 22 and the projection lens system 40. The spacer 104 laterally surrounds the VCSELs 22 and serves as sidewalls for the module. In some cases, the module is compact with a relatively small footprint and small z-height.

The systems and methods described above for creating and projecting structured light can be used, for example, in association with various imaging systems, such as three-dimensional imaging and video systems. Further, structured light projection systems as described above, or modules incorporating such structured light projection systems, can be integrated into a wide range of host devices such as smartphones, laptops, wearable devices and other computing devices that may have with networking capability. The host devices may include processors and other electronic components, and other supplemental modules configured to collect data, such as cameras, time-of-flight imagers. Other supplemental modules may be included such as ambient lighting, display screens, automotive headlamps, and the like. The host devices may further include non-volatile memory where instructions for operating the optoelectronic modules, and in some instances the supplemental modules, are stored.

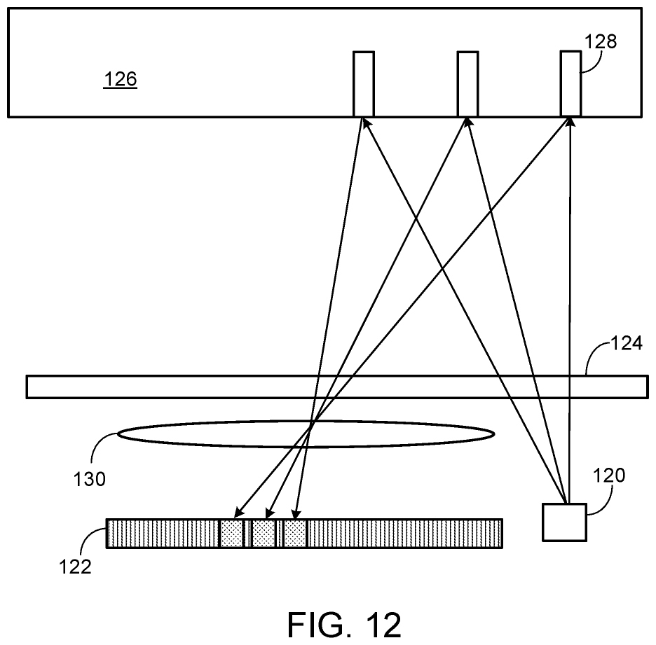

FIG. 12 illustrates an example of an optoelectronic system includes a structured light projector 20 as described above and operable to project a structured light pattern 128 onto one or more objects in a scene 126 of interest. In some implementations, the projected pattern consists of light in the IR or near-IR region of the spectrum. Light from the projected pattern 128 can be reflected by the object(s) in the scene 126 and sensed by an image sensor 122 that includes spatially distributed light sensitive components (e.g., pixels) that are sensitive to a wavelength of light emitted by the light projector 20. In some cases, one or more optical elements such as lenses 130 help direct the light reflected from the scene 126 toward the image sensor 122. The detected signals can be read-out and used, for example, by processing circuitry for stereo matching to generate a three-dimensional image. The processing circuitry can be operable to determine a physical characteristic of the object based at least in part on a signal from the sensor, and/or to use data obtained by the optical sensor for one or more functions executed by the host device. Using structured light can be advantageous, for example, in providing additional texture for matching pixels in the stereo images.

In some implementations, the light projector 20, the lenses 128 and the image sensor 122 are integrated within a host computing device (e.g., a smartphone). In such cases, the light projector 20, the lenses 28 and the image sensor 22 can be disposed below a front side cover glass 124 of the host device. The structured light emitted by the light projector 20 can result in a pattern 128 of discrete features (i.e., texture or encoded light) being projected onto objects in the scene 126 external to the host device. In some instances, the light projector 20, the lenses 128 and the image sensor 122 are components of the same optoelectronic module. In other implementations, the light projector 20 can be a discrete component that is not integrated into the same module as the image sensor 122 and/or lens 128. Further, the light projector 210 can be used in other types of applications (e.g., proximity sensing, distance determinations using triangulation) as well and is not limited to the imaging applications referred to above.

Modules incorporating a structured light projection system as described above can, in some instances, obtain more accurate data than other techniques. Thus, functions performed by the host device based on signals emitted from the structured light projection system can be performed more accurately, thereby conferring substantial advantages to the smartphone or other host device.

Although a broad framework of the disclosure is described with reference to various preferred embodiments, other implementations may include combinations and sub-combinations of elements described in this disclosure. For example, features described in connection with different implementations above may, in some cases, be combined in the same implementation. Thus, other implementations are within the scope of the claims.

1. A method of creating an irregular structured light pattern from a regular array of light emitting elements, the method comprising:
generating a regular pattern of light from a uniformly distributed array of light emitting elements;
altering the regular pattern of light to generate an irregular pattern of light; and
reproducing the irregular pattern of light in multiple instances arranged adjacent one another.

2. The method of claim 1 wherein the array of light emitting elements includes columns and rows of light emitting elements, wherein the rows are either:
arranged perpendicularly relative to the columns; or
angled relative to the columns.

3. (canceled)

4. The method of claim 1 wherein the array of light emitting elements produces a regular pattern of a sub pattern of lights.

5. The method of claim 1 wherein the array of light emitting elements produces a grid of a cluster of lights, wherein the grid has commonly shaped clusters in a first direction, and wherein the grid has differently shaped clusters in a second direction perpendicular to the first direction.

6. The method of claim 1 further including receiving light emitted from the array of light emitting elements and project the light to a first diffractive optical element to generate the irregular pattern of light.

7. The method of claim 1 wherein the irregular pattern of light is at least one of a randomized, non-uniform, non-grid, disrupted, unevenly spaced, partially obstructed, partially blocked, and/or non-equally distributed pattern.

8. The method of claim 1 wherein reproducing the irregular pattern in multiple instances arranged relative to one another includes producing a uniform distribution of the irregular pattern.

9. The method of claim 1 wherein reproducing the irregular pattern of light includes producing one of:
a tiled pattern; or
multiple interlaced instances of the irregular pattern of light; or
multiple partially overlapping instances of the irregular pattern of light.

10.-11. (canceled)

12. A structured light projection system comprising:
an array of light emitting elements operable, collectively, to emit a regular pattern of light;
a first optical element configured to alter the pattern of light emitted by the array of light emitting elements to generate a first irregular pattern of light; and
a second optical element configured to receive the irregular pattern of light generated by the first optical element and to produce a pattern comprising multiple instances of the first irregular pattern.

13. The structured light projection system of claim 12 wherein the array of light emitting elements includes columns and rows of light emitting elements, wherein the rows are either:
arranged perpendicularly relative to the columns; or
angled relative to the columns.

14. (canceled)

15. The structured light projection system of claim 12 wherein the array of light emitting elements is operable to project a regular pattern of a sub pattern of lights.

16. The structured light projection system of claim 12 wherein the array of light emitting elements is operable to project a grid of a cluster of lights, wherein the grid has commonly shaped clusters in a first direction, and wherein the grid has differently shaped clusters in a second direction perpendicular to the first direction.

17. The structured light projection system of claim 12 further including a projection lens system operable to receive light emitted from the array of light emitting elements and to project the light to the first optical element.

18. The structured light projection system of claim 12 wherein the first irregular pattern of light is at least one of a randomized, non-uniform, non-grid, disrupted, unevenly spaced, partially obstructed, partially blocked, and/or non-equally distributed pattern.

19. The structured light projection system of claim 12 wherein the second optical element is arranged to produce a uniform distribution of the irregular pattern.

20. The structured light projection system of claim 12 wherein the second optical element is arranged to produce one of:
a tiled pattern; or
multiple interlaced instances of the irregular pattern of light; or
multiple partially overlapping instances of the irregular pattern of light.

21.-22. (canceled)

23. The structured light projection system of claim 12 wherein each of the first and second optical elements comprises a diffractive optical element.

24. The structured light projection system of claim 12 wherein the light emitting elements are VCSELs.

25. An optical sensor module comprising:
an optical source including a structured light projection system according to claim 12, the structured light projection system being operable to project a structured light pattern onto an object;
an optical sensor to sense light reflected back from the object illuminated by the structured light pattern; and
processing circuitry operable to determine a physical characteristic of the object based at least in part on a signal from the optical sensor.

26. A host device comprising an optical sensor module according to claim 25, wherein the host device is operable to use data obtained by the optical sensor of the optical sensor module for one or more functions executed by the host device; and, optionally, wherein the host device is a smartphone.
